(19) United States
(12) Patent Application Publication
(10) Pub. No.: US 2021/0272907 A1
(43) Pub. Date: Sep. 2, 2021

(54) REDISTRIBUTION LAYER OF FAN-OUT PACKAGE AND MANUFACTURING METHOD THEREOF

(71) Applicant: Powertech Technology Inc., Hukou Township (TW)

(72) Inventors: Ming-Yi WANG, Hukou Township (TW); Yu-Ping WANG, Hukou Township (TW)

(73) Assignee: Powertech Technology Inc., Hukou Township (TW)

(21) Appl. No.: 16/879,028

(22) Filed: May 20, 2020

(30) Foreign Application Priority Data
Feb. 27, 2020 (TW) 109106532

(51) Int. Cl. H01L 23/538; H01L 21/48

(52) U.S. Cl. CPC H01L 23/5386; H01L 21/4857; H01L 23/5383

(57) ABSTRACT

A redistribution layer of fan-out package and manufacturing method thereof is disclosed. Before forming a pattern wiring layer on each dielectric insulation layer, a thin metal ion layer is formed firstly. A connection between the metal ion layer and the corresponding dielectric insulation layer is weaker than that between the patterned wiring layer and the corresponding dielectric insulation layer. When the redistribution layer is placed in a high temperature and high humidity environment, the stress generated by the patterned circuit layer causes that multiple gaps to form between the metal ion layers and the corresponding dielectric insulating layer. Therefore, a distance between the adjacent dielectric insulating layer and the patterned wiring layer is increased to reduce the capacitive effect and the power consumption of the thinner redistribution layer.

### BACKGROUND OF THE INVENTION

### 1. Field of the Invention

The present invention is related to a semiconductor package, and more particularly to a redistribution layer of a fan-out package and manufacturing method thereof.

### 2. Description of the Prior Arts

With reference to FIG. 5A, a redistribution layer 70 of a fan-out package is shown and formed on a base layer 80 of the fan-out package. The redistribution layer 70 has multiple dielectric layers 71 and multiple wiring layers 72. The dielectric layers 71 and wiring layers 72 are sequentially stacked on the base layer 80. Specifically, one of the dielectric layer 71 is formed on the base layer 80 and one of the wiring layers 72 is formed on the dielectric layer 71 on the base layer 80. Then another dielectric layer 72 is formed on the wiring layer 72. Repeat this forming sequence until all dielectric layers 71 and multiple wiring layers 72 are alternately stacked on the base layer 80 to complete the redistribution layer 70.

With reference to FIG. 5A, the dielectric layer between two adjacent wiring layers 72 has a thickness and the thickness corresponds to a distance d1 between the two adjacent wiring layers 72. According to an equation of capacitance (C=ε·A/L; C: capacitance, ε: dielectric constant, A: overlapped area, L: distance), if the distance between the two adjacent wiring layers 72 is decreased, a capacitive effect is relatively increased. As shown in FIG. 5B, by thinning a thickness of each of the dielectric layers 71′ of the redistribution, a thickness of the fan-out package is decreased. However, in a thinner fan-out package, the distance d2 between the two adjacent wiring layers 72 is shorter (d2<d1), too. Therefore, the capacitive effect is relatively increased. According to an equation of power (W=C·V²; W: power, C: capacitance, V: component voltage), if the capacitance of the redistribution layer 70a is increased but the component voltage is not changed, a whole power consumption is relatively increased.

To overcome the shortcomings of the thinner redistribution layer of the fan-out package, the present invention provides a new redistribution layer of a fan-out package to mitigate or obviate the aforementioned problems.

### SUMMARY OF THE INVENTION

An objective of the present invention is to provide a redistribution layer of a fan-out package and manufacturing method thereof.

To achieve the objective as mentioned above, the redistribution layer of the fan-outpackage has:

Based on the foregoing description,

To achieve the objective as mentioned above, the method of manufacturing the redistribution layer of the fan-outpackage has steps of:

Based on the foregoing description,

Other objectives, advantages and novel features of the invention will become more apparent from the following detailed description when taken in conjunction with the accompanying drawings.

### BRIEF DESCRIPTION OF THE DRAWINGS

FIG. 1 is a cross-sectional view of a first embodiment of a redistribution layer in accordance with the present invention;

FIG. 2 is a cross-sectional view of a second embodiment of a redistribution layer in accordance with the present invention;

FIGS. 3A to 3L are multiple cross-sectional views in different steps of a method of manufacturing a redistribution in accordance with the present invention;

FIGS. 4A to 4F are multiple cross-sectional views in different steps of another method of manufacturing a redistribution in accordance with the present invention;

FIG. 5A is a cross-sectional view of a conventional redistribution layer in accordance with the prior art; and

FIG. 5B is a cross-sectional view of another conventional redistribution layer in accordance with the prior art.

### DETAILED DESCRIPTION OF THE PREFERRED EMBODIMENTS

The present invention provides a thinner redistribution layer of a fan-out package with less capacitive effect and less power consumption. According to the drawings, details of the thinner redistribution layer of the fan-out package are described as follows.

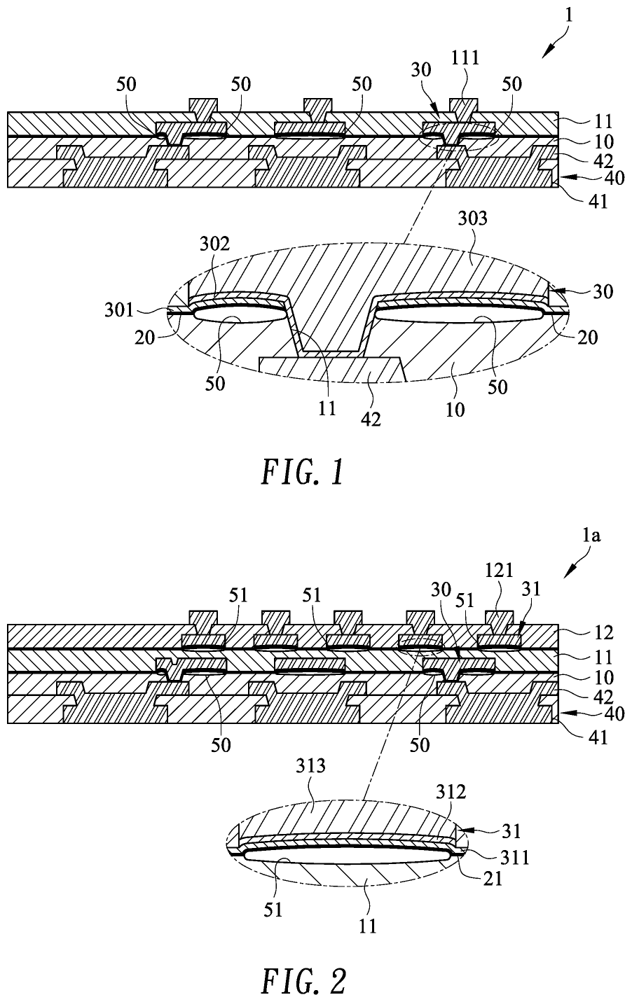

With reference to FIG. 1, a first embodiment of a redistribution layer 1 of the present invention is shown. In the preferred embodiment, the retribution layer 1 is a 2P1M (two PI layers and one metal layer) redistribution layer and formed on a base layer 40. The redistribution layer 1 has a first dielectric insulation layer 10, a first metal ion layer 20, a first patterned wiring layer 30 and a second dielectric insulation layer 11. In the preferred embodiment, the base layer 40 is a wiring layer or an active surface having multiple metal pads of a chip. The wiring layer has an insulation layer 41 and multiple metal lines 42 embedded in the insulation layer 41. The metal lines 42 further extends to a top surface of the insulation layer 41.

The first dielectric insulation layer 10 is formed on the top surface of the insulation layer 41 of the base layer 40 and covers parts of the metal lines on the top surface of the insulation layer 11. Multiple through holes 101 are formed through the first dielectric layer 10 and each of the through holes corresponds to the corresponding part of the metal line 42 on the top surface of the insulation layer 11. In the preferred embodiment, the thickness of the first dielectric insulation layer 10 is 0.1 μm to 10 μm.

The first metal ion layer 20 is formed on the first dielectric insulation layer 10. A connection between the metal ion layer 20 and the first dielectric insulation layer 10 is weaker than that between the first patterned wiring layer and the first dielectric insulation layer 10. Particularly, the first metal ion layer 20 is formed by implanting 1 at % to 20 at % of copper ions, iron ions, manganese ions, aluminum ions or 1 at % to 20 at % of the combination thereof on a top surface of the first dielectric insulation layer 10 and a thickness of the first metal ion layer 20 is about 20 nm to 500 nm.

The first patterned wiring layer 30 is formed on the first metal ion layer 20 and multiple first gaps 50 are formed between the first patterned insulation layer 30 and the first dielectric insulation layer 10. Multiple overlapped areas between the first patterned wiring layer 30 and the first dielectric insulation layer 10 do not contact with each other. In the preferred embodiment, the first patterned wiring layer 30 has a Ti barrier layer 301 part, a copper seed layer 302 and a copper layer 303. The Ti barrier layer 301 part corresponds to the copper seed layer 302 and the copper layer 303. A thickness of the first patterned wiring layer 30 is substantially equal to 200 μm. Therefore, a thickness of the first metal ion layer 20 may be 0.01 at %-0.25 at % of the thickness of the first patterned wiring layer 30. A height of the first gap 50 is 50 nm to 500 nm.

The second dielectric insulation layer 11 is formed on the first metal ion layer 20 and the first pattern wiring layer 30. In the preferred embodiment, the second dielectric insulation layer 11 further has multiple conductive vias 111. Each of the conductive vias 111 corresponds to a corresponding part of the first patterned wiring layer 30. In the preferred embodiment, a thickness of the second dielectric insulation layer 11 is 0.1 μm to 10 μm.

With reference to FIG. 2, a second embodiment of the redistribution layer 1a of the present invention is shown. In the preferred embodiment, the redistribution layer 1a is a 3P3M (three PI layers and three metal layers) redistribution layer and formed on a base layer 40. The redistribution layer 1a has a first dielectric insulation layer 10, a metal ion layer 20, a first patterned wring layer 30, a second dielectric insulation layer 11, a second metal ion layer 21, a second patterned wiring layer 31 and a third dielectric insulation layer 12. The first dielectric insulation layer 10, the metal ion layer 20, the first patterned wring layer 30, the second dielectric insulation layer 11 are the same as these of the first embodiment as shown in FIG. 1.

The second metal ion layer 21 is formed on the second dielectric layer 11. A connection between the metal ion layer 21 and the second dielectric insulation layer 11 is weaker than that between the patterned wiring layer 31 and the second dielectric insulation layer 11. Particularly, the second metal ion layer 21 is formed by implanting 1 at % to 20 at % of copper ions, iron ions, manganese ions, aluminum ions or 1 at % to 20 at % of the combination thereof on a top surface of the second dielectric insulation layer 11 and a thickness of the second metal ion layer 21 is about 20 nm to 500 nm.

The second patterned wiring layer 31 is formed on the second metal ion layer 21 and multiple second gaps 51 are formed between the second patterned wiring layer 31 and the second dielectric layer 11. Multiple overlapped areas between the second patterned wiring layer 31 and the dielectric insulation layer 11 are not contacted. In the preferred embodiment, a height of each second gap 51 is 50 nm-500 nm.

The third dielectric insulation layer 12 is formed on the second metal ion layer 21 and the second patterned wiring layer 31. In a preferred embodiment, the third dielectric insulation layer 12 further has multiple conductive vias 121. Each of the conductive vias 121 corresponds to a corresponding part of the second patterned wiring layer 31.

Based on the foregoing description, in the redistribution layer 1, la, before the first and second patterned wiring layers 30, 31 are respectively formed on the first and second dielectric insulation layers 10, 11, the first and second metal ion layers 20, 21 with thin thicknesses are respectively formed. The connection between the metal ion layer 20 and the first dielectric insulation layer 10 is weaker than that between the first patterned wiring layer 30 and the first dielectric insulation layer 10, and the connection between the metal ion layer 21 and the second dielectric insulation layer 11 is weaker than that between the patterned wiring layer 31 and the second dielectric insulation layer 11. When the redistribution layer 1, la is placed in a high temperature and high humidity environment, the stress generated by the first and second patterned circuit layers 30, 31 causes the first gaps 50 to form between the first metal ion layers 20 and the first dielectric insulating layers 10, and causes the second gaps 51 to form between the second metal ion layers 21 and the second dielectric insulating layers 11. Therefore, distances between the adjacent dielectric insulating layer and the patterned wiring layer are increased to reduce the capacitive effect of the thinner redistribution layer 1, la.

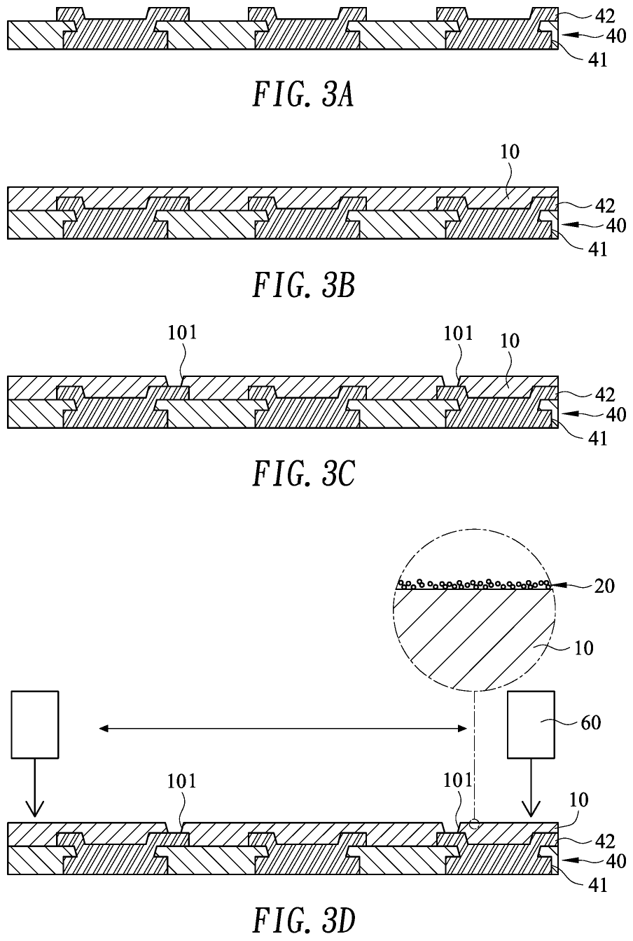

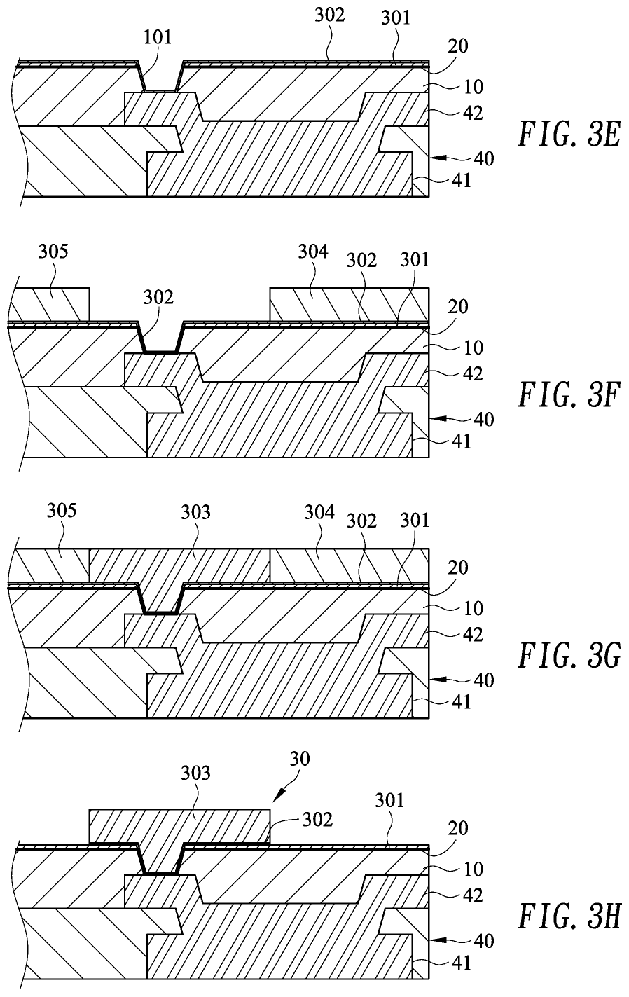

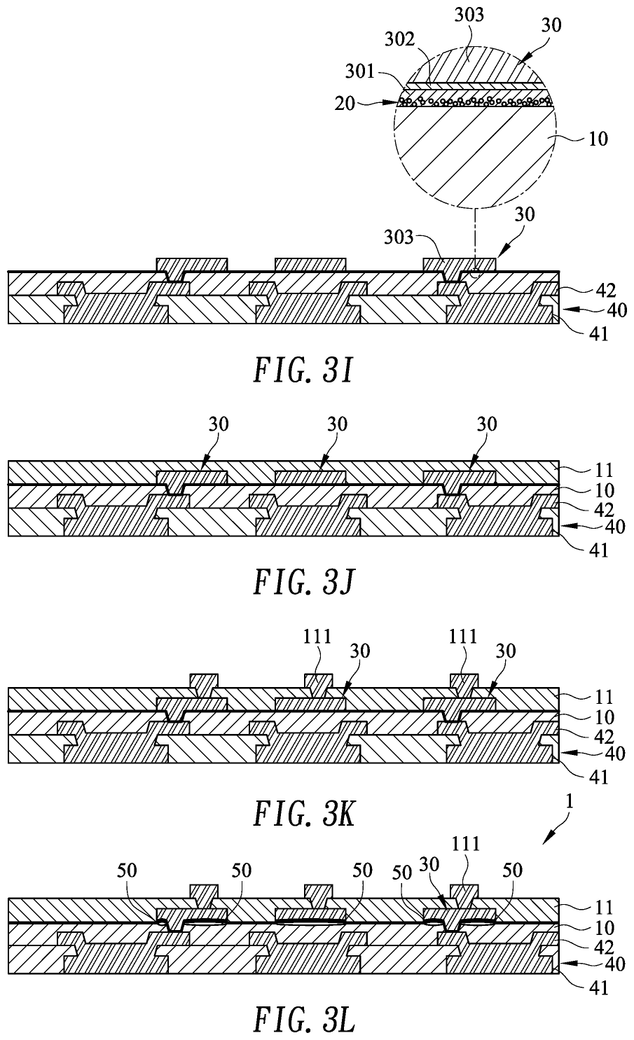

With reference to FIGS. 3A to 3K, a method of manufacturing the redistribution layer as shown in FIG. 1 has following steps of (a) to (e).

In the step (a), as shown in FIG. 3A, a base layer is provided. As shown in FIG. 3B, a first dielectric insulation layer 10 is formed on the first dielectric insulation layer 10. In the preferred embodiment, the base layer 40 has an insulation layer 41 and multiple metal lines 42 embedded inside the insulation layer 41. The metal lines 42 further extend to a top surface of the insulation layer 41 and multiple through holes 101 are formed through the first dielectric insulation layer 10. As shown in FIG. 3C, each through hole 101 corresponds to a part of the metal lines 42 on the top surface of the insulation layer 41. Particularly, a thickness of the first dielectric insulation layer 10 is 0.1 μm to 10 μm.

In the step (b), as shown in FIG. 3D, a first metal ion layer 20 is implanted in a top surface of the first dielectric insulation layer 10. In the preferred embodiment, the first metal ion layer 20 is implanted in the top surface of the first dielectric insulation layer 10 by an ion gun. The ion gun implants 1 at % to 20 at % of copper ions, iron ions, manganese ions, aluminum ions or 1 at % to 20 at % of the combination thereof in the top surface of the first dielectric insulation layer 10 and inside walls of the through holes 101.

In the step (c), as shown in 31, a first pattern wiring layer 30 is formed on the first metal ion layer 20. Particularly, the first pattern wiring layer 30 is formed by following steps of (c1) to (c5). In the step (c1), as shown in FIG. 3E, a Ti barrier layer 301 is formed on the top surface of the first dielectric insulation layer 10 by PVD process to connect the first metal ion layer 20. A copper seed layer 302 is formed on the Ti barrier layer 301. The copper seed layer 302 is further formed on the inside walls of each through hole 101 of the first dielectric insulation layer 10. In the step (c2), a photoresist layer 304 is formed on the copper seed layer 302. As shown in FIG. 3F, multiple openings 305 are formed on the photoresist layer 304 by a photolithography process. In step (c3), as shown in FIG. 3G, a copper layer 303 is formed in each opening 305 of the photoresist layer 304 by an electroless plating process. In the step (c4), as shown in FIG. 3H, the photoresist layer 304 is removed. In the step (c5), multiple parts of the copper seed layer 302 exposed from the copper layers 303 are etched. Therefore, as shown in FIG. 3I, the first patterned wiring layer 30 has multiple parts of the Ti barrier layer 301, a copper seed layer 302 and copper layer 303. The parts of the Ti barrier layer 301 correspond to the copper seed layer 302 and copper layer 303.

In the step (d), as shown in FIGS. 31 and 3J, a second dielectric insulation layer 11 is formed on the first metal ion layer 20 and the first patterned wiring layer 30. As shown in FIG. 3K, multiple conductive vias 111 corresponding to parts of the first patterned wiring layer 30 are formed through the second dielectric insulation layer 11. Particularly, A thickness of the second dielectric insulation layer 11 is 0.1 μm to 10 μm.

In the step (e), as shown in FIG. 3L, multiple first air gaps 50 are formed between the first patterned wiring layer 30 and the first electric insulation layer 10 in a high temperature and moisture environment. Multiple overlapped areas between the first patterned wiring layer 30 and the first dielectric insulation layer 10 do not contact with each other. In a preferred embodiment, the temperature may be 130° C. and the moisture may be 85% in a high temperature and moisture environment. Furthermore, if an atom percentage of iron ions included in the first metal ion layer 20 is higher, the time of forming the first gaps 50 is shorter.

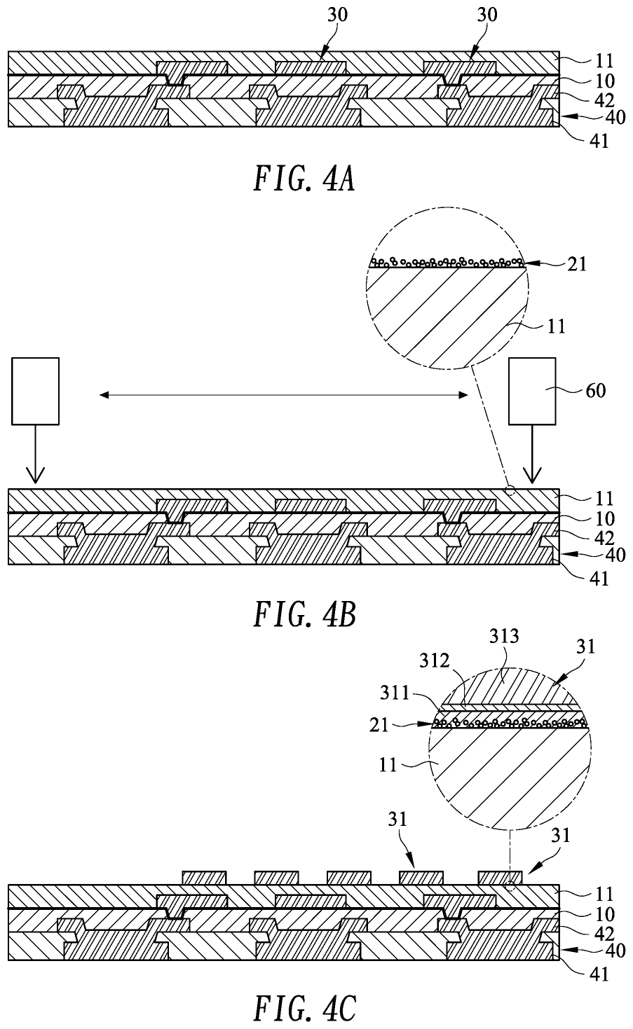

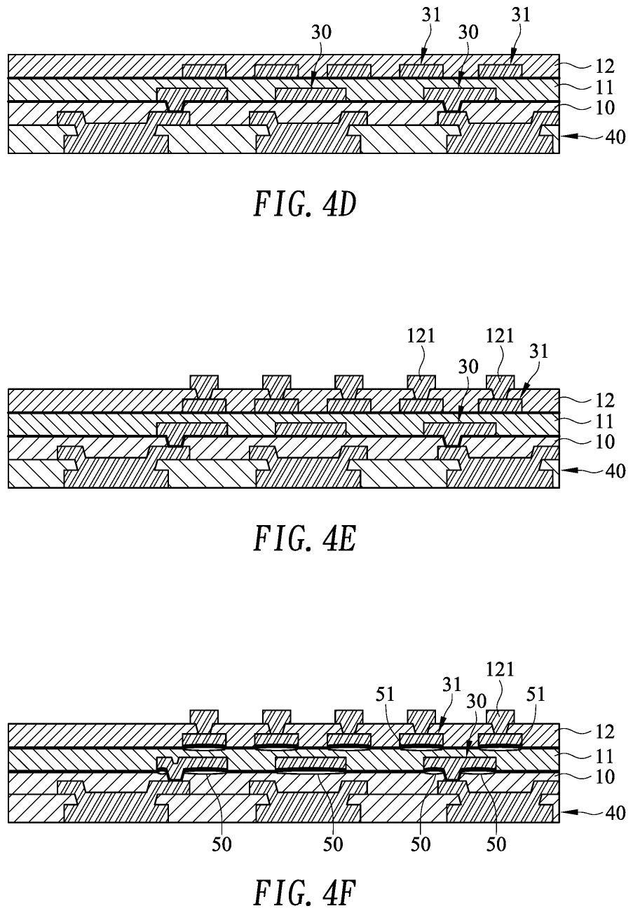

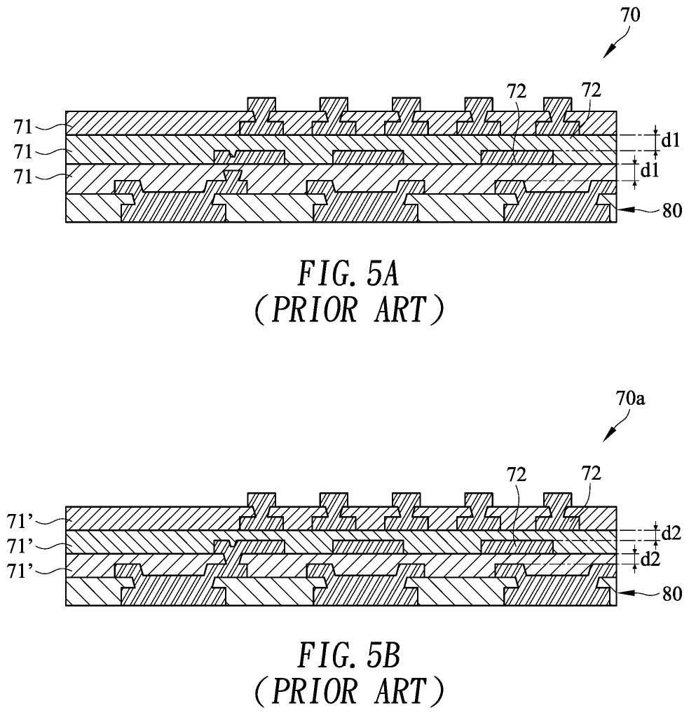

With reference to FIGS. 4A to 4F, a method of manufacturing the redistribution layer 1a of FIG. 2 has steps of (a) to (h). Since the first dielectric insulation layer 10, the first metal ion layer 20, the first patterned wiring layer 30 and a second dielectric insulation layer 11 are the same as those of first embodiment, the steps of (a) to (c) in the second embodiment are the same as the steps of (a) to (c) in the first embodiment as shown in FIGS. 3A to 3J and not repeated here. The steps of (d) to (h) in the second embodiment are further described as follows.

In the step (d), as shown in FIGS. 31 and 4A, the second dielectric insulation layer 11 is formed on the first metal ion layer 20 and the first patterned wiring layer 30. Particularly, A thickness of the second dielectric insulation layer 11 is 0.1 μm to 10 μm.

In the step (e), as shown in FIG. 4B, a second metal ion layer 21 is implanted in the top surface of the second dielectric insulation layer 11. In the preferred embodiment, the ion gun 60 implants 1 at % to 20 at % of copper ions, iron ions, manganese ions, aluminum ions or 1 at % to 20 at % of the combination thereof in the top surface of the second dielectric insulation layer 11.

In the step (f), as shown in FIG. 4C, a second patterned wiring layer 31 is formed on the second metal ion layer 21. In preferred embodiment, the second patterned wiring layer 31 has multiple parts of the Ti barrier layer 311, a copper seed layer 312 and copper layer 313. The parts of the Ti barrier layer 311 correspond to the copper seed layer 312 and copper layer 313.

In the step (g), as shown in FIGS. 4D and 4E, a third dielectric insulation layer 12 is formed on the second metal ion layer 21 and the second patterned wiring layer 31. Multiple conductive vias 121 corresponding to parts of the second patterned wiring layer 31 are formed through the third dielectric insulation layer 12. Particularly, A thickness of the third dielectric insulation layer 12 is 0.1 μm to 10 μm.

In the step (h), as shown in FIG. 4F, multiple first air gaps 50 are formed between the first patterned wiring layer 30 and the first electric insulation layer 10. Multiple second air gaps 51 are formed between the second patterned wiring layer 31 and the second electric insulation layer 11 in a high temperature and moisture environment. Multiple overlapped areas between the first patterned wiring layer 30 and the first dielectric insulation layer 10 do not contact with each other. Multiple overlapped areas between the second patterned wiring layer 31 and the second dielectric insulation layer 11 do not contact with each other. In preferred embodiment, the temperature may be 130° C. and the moisture may be 85% in a high temperature and moisture environment. Furthermore, if an atom percentage of iron ions included in the first and second metal ion layers 20, 21 are higher, the time of forming the first and second gaps 50, 51 is shorter.

Based on the foregoing description, in the method of manufacturing the redistribution layer, the first and second metal ion layers 20, 21 with thin thicknesses are respectively formed before the first and second patterned wiring layers re respectively formed on the first and second dielectric insulation layers. The connection between the metal ion layer and the first dielectric insulation layer is weaker than that between the first patterned wiring layer and the first dielectric insulation layer, and the connection between the metal ion layer and the second dielectric insulation layer is weaker than that between the patterned wiring layer and the second dielectric insulation layer. When the redistribution layer is placed in the high temperature and high humidity environment, the stress generated by the first and second patterned circuit layers causes the first gaps to form between the first metal ion layers and the first dielectric insulating layers, and causes the second gaps to form between the second metal ion layers and the second dielectric insulating layers. Therefore, distances between the adjacent dielectric insulating layer and the patterned wiring layer are increased to reduce the capacitive effect of the thinner redistribution layer. Also, the power consumption of the thinner redistribution layer is not increased.

Even though numerous characteristics and advantages of the present invention have been set forth in the foregoing description, together with the details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

1. A redistribution layer of fan-out package, comprising:
a first dielectric insulation layer adapted to form on a base layer;
a metal ion layer formed on the first dielectric insulation layer;
a first pattern wiring layer formed on the first metal ion layer, wherein multiple first gaps are formed between the first patterned wiring layer and the first dielectric insulation layer; and
a second dielectric insulation layer formed on the first metal ion layer and the first pattern wiring layer.

2. The redistribution layer as claimed in claim 1, further comprising:
a second metal ion layer formed on the second dielectric insulation layer;
a second patterned wiring layer formed on the second metal ion layer, wherein multiple second gaps are formed between the second patterned wiring layer and the second dielectric insulation layer; and
a third dielectric insulation layer formed on the second metal ion layer and the second pattern wiring layer.

3. The redistribution layer as claimed in claim 2, wherein:
the first dielectric insulation layer further has multiple first conductive vias and each of the first conductive vias is connected to the first patterned wiring layer; and
the third dielectric insulation layer further has multiple second conductive vias and each of the second conductive vias is connected to the second patterned wiring layer.

4. The redistribution layer as claimed in claim 2, wherein:
the first and second patterned wiring layer are made of Ti or Cu; and
the first and second metal ion layers are made of 1 at % to 20 at % of copper ions, iron ions, manganese ions, aluminum ions or 1 at % to 20 at % of the combination thereof.

5. The redistribution layer as claimed in claim 3, wherein:
the first and second patterned wiring layer are made of Ti or Cu; and
the first and second metal ion layers are made of 1 at % to 20 at % of copper ions, iron ions, manganese ions, aluminum ions or 1 at % to 20 at % of the combination thereof.

6. The redistribution layer as claimed in claim 4, wherein:
a thickness of each of the first and second metal ion layers is 20 nm to 500 nm;
a thickness of each of the first to third dielectric insulation layers is 0.1 μm to 10 μm; and
a height of each of the first and second gaps is 50 nm to 500 nm.

7. The redistribution layer as claimed in claim 5, wherein:
a thickness of each of the first and second metal ion layers is 20 nm to 500 nm;
a thickness of each of the first to third dielectric insulation layers is 0.1 μm to 10 μm; and
a height of each of the first and second gaps is 50 nm to 500 nm.

8. A method of manufacturing a redistribution layer of fan-out package, comprising steps of:
(a) forming a first dielectric insulation layer on a base layer;
(b) implanting a metal ion layer in the first dielectric insulation layer;
(c) forming a patterned wiring layer on the metal ion layer;
(d) forming a second dielectric insulation layer on the metal ion layer and the patterned wiring layer; and
(e) forming a gap between the patterned wiring layer and the first dielectric insulation layer in a high temperature and humidity environment.

9. The method as claimed in claim 8, wherein in the step (b), an ion gun implants metal ions in the first dielectric insulation layer to form the metal ion layer;
and the step (c) has steps of:
(c1) sequentially forming a Ti barrier layer and a copper seed layer on the metal ion layer by physical vapor deposition;
(c2) forming a photoresist layer on the copper seed layer and forming multiple openings through the photoresist layer by photolithography process;
(c3) forming a copper layer in each of the openings of the photoresist layer by electroless plating to form the patterned wiring layer;
(c4) removing the photoresist layer; and
(c5) etching multiple parts of the copper seed layer exposed from the copper layer.

10. The method as claimed in claim 9, wherein in the step (b), the ion gun implants 1 at % to 20 at % of copper ions, iron ions, manganese ions, aluminum ions or 1 at % to 20 at % of the combination thereof in the first dielectric insulation layer to form the metal ion layer.

11. The method as claimed in claim 9, wherein:
in the step (a), patterning the first dielectric insulation layer to form multiple through holes through the first dielectric insulation layer;
in the step (c 1), the copper seed layers are formed on inner walls of the corresponding through holes;
in the step (c3), filling copper in each of the through holes to form the conductive vias.

12. The method as claimed in claim 10, wherein:
in the step (a), patterning the first dielectric insulation layer to form multiple through holes through the first dielectric insulation layer;
in the step (c1), the copper seed layers are formed on inner walls of the corresponding through holes;
in the step (c3), filling copper in each of the through holes to form the conductive vias.

13. The method as claimed in claim 11, wherein:
a thickness of the metal ion layer is 20 nm to 500 nm;
a thickness of each of the first and second dielectric insulation layers is 0.1 μm to 10 μm; and
a height of each of gap is 50 nm to 500 nm.

14. The method as claimed in claim 12, wherein:
a thickness of the metal ion layer is 20 nm to 500 nm;
a thickness of each of the first and second dielectric insulation layers is 0.1 μm to 10 μm; and
a height of each of gap is 50 nm to 500 nm.

15. The redistribution layer as claimed in claim 3, wherein:
the first and second patterned wiring layer are made of Ti or Cu; and
the first and second metal ion layers are made of 1 at % to 20 at % of copper ions, iron ions, manganese ions, aluminum ions or 1 at % to 20 at % of the combination thereof.

16. The redistribution layer as claimed in claim 15, wherein:
a thickness of each of the first and second metal ion layers is 20 nm to 500 nm;
a thickness of each of the first to third dielectric insulation layers is 0.1 μm to 10 μm; and
a height of each of the first and second gaps is 50 nm to 500 nm.
